(19) United States
(12) Patent Application Publication
(10) Pub. No.: US 2022/0206548 A1
(43) Pub. Date: Jun. 30, 2022

(54) PULSE WIDTH MODULATION AND VOLTAGE TEST SIGNALS FOR FAN TYPE DETECTION

(71) Applicant: Hewlett-Packard Development Company, L.P., Spring, TX (US)

(72) Inventors: Hsiang Chuan Sung, Taipei City (TW); Chien Hao Chen, Taipei City (TW); Fu-Yi Chen, Taipei City (TW); Yi-Hsuan Huang, Taipei City (TW); Chi-feng Chen, Taipei City (TW)

(73) Assignee: Hewlett-Packard Development Company, L.P., Spring, TX (US)

(21) Appl. No.: 17/599,828

(22) PCT Filed: Jul. 24, 2019
(86) PCT No.: PCT/US2019/043265

§ 371 Date: Sep. 29, 2021

(51) Int. Cl. G06F 1/20; H05K 7/20; G01P 3/489

(52) U.S. Cl. CPC G06F 1/20; G01P 3/489; H05K 7/20209

(57) ABSTRACT

An example non-transitory machine-readable storage medium includes instructions to determine whether a cooling fan is controlled by pulse wave modulation (PWM) or is voltage-controlled. When executed, the instructions cause a processor of a computing device to transmit first and second PWM test signals at different PWM duties to a fan connector connected to the cooling fan, receive a first and second fan speed signals in response, and determine, when the first fan speed signal is not equal to the second fan speed signal, that the cooling fan is a PWM-controlled fan. The instructions further cause the processor to transmit first and second voltage test signals at different voltages to the fan connector, receive a third fan and fourth speed signal in response, and determine, when the third fan speed signal is not equal to the fourth fan speed signal, that the cooling fan is a voltage-controlled fan.

### BACKGROUND

A cooling fan for a desktop or laptop computer may be either a three-pin voltage-controlled fan or a four-pin fan controlled by pulse width modulation (PWM). A voltage-controlled fan may be controlled to operate at different fan speeds based on the voltage transmitted to the fan. Similarly, a PWM-controlled fan may be controlled to operate at different fan speeds based on the PWM duty transmitted to the fan. A motherboard of a computer generally includes a universal four-pin fan connector that can be used to operate with both varieties, provided that it is known which type of cooling fan is connected.

### BRIEF DESCRIPTION OF THE DRAWINGS

FIG. 1 is a schematic diagram of an example non-transitory machine-readable storage medium storing instructions to cause a processor of a computing device to determine whether a cooling fan connected to a fan connector is a PWM-controlled fan or a voltage-controlled fan.

FIG. 2 is a schematic diagram of another example non-transitory machine-readable storage medium storing instructions to cause a processor of a computing device to determine whether a cooling fan connected to a fan connector is a PWM-controlled fan or a voltage-controlled fan.

FIG. 3 is an example decision-making matrix to make a definitive determination of whether a cooling fan connected to a fan connector is a PWM-controlled fan or a voltage-controlled fan based on tentative determinations.

FIG. 4 is a schematic diagram of an example device including a cooling fan, a fan connector to connect to the cooling fan, and an embedded controller to determine whether the cooling fan is a PWM-controlled fan or a voltage-controlled fan.

FIG. 5 is a schematic diagram of another example device including a cooling fan, a fan connector to connect to the cooling fan, and an embedded controller to determine whether the cooling fan is a PWM-controlled fan or a voltage-controlled fan, the device further including a voltage control (VC) fan controller to transmit voltage test signals to the cooling fan.

### DETAILED DESCRIPTION

A fan connector for a desktop or laptop computer is generally capable of operating with either a three-pin voltage-controlled cooling fan or four-pin PWM-controlled cooling fan interchangeably, provided that it is known which type of fan is connected to the fan connector. A computer therefore typically includes an embedded controller (EC) located on the motherboard connected to the fan connectors to determine the type of fans connected to them. Such ECs may include various signal testing systems to conduct testing procedures to determine which type of fan is connected to a particular fan connector. Such testing systems may include expensive electronic components and circuitry, and such testing procedures may be computationally intensive. Further, such testing procedures may fail where the fan being tested is faulty.

An embedded controller is provided herein which tests a fan connector for a connected fan type by conducting a PWM control test, conducting a voltage control test, and determining the connected fan type based on the combination of test results. Such testing may be conducted without expensive electronic components and circuitry, without computationally intensive testing procedures, and includes redundancy to determine whether a fan is PWM-controlled, and voltage-controlled, or is faulty.

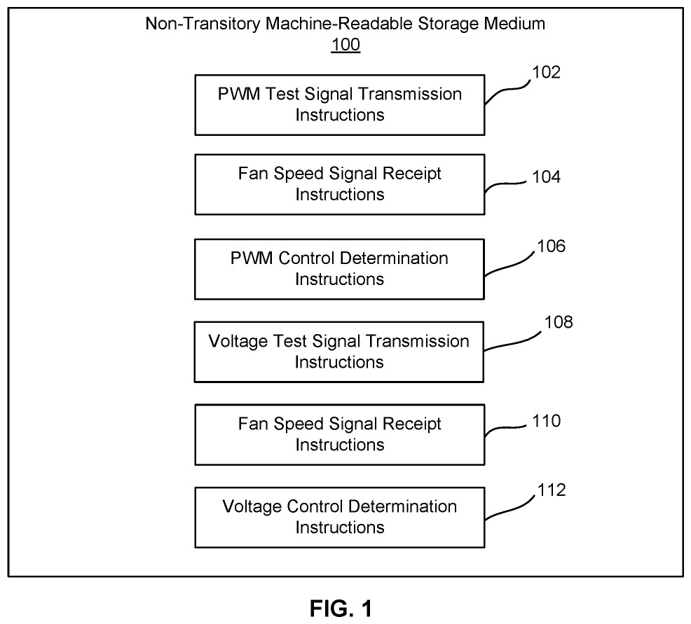

FIG. 1 is a schematic diagram of an example non-transitory machine-readable storage medium 100. The storage medium stores instructions to cause a processor of a computing device to determine whether a cooling fan connected to a fan connector is a PWM-controlled fan or a voltage-controlled fan. The computing device may include a desktop computer, laptop computer, or any other computing device that is capable of operating with four-pin PWM-controlled fans and three-pin voltage-controlled fans through fan connectors that may connect to either type of cooling fan. The processor may include an embedded controller connected to a motherboard of the computing device to which the fan connector is connected.

The storage medium 100 includes PWM test signal transmission instructions 102 to cause the processor to transmit first and second PWM test signals at different PWM duties to the fan connector connected to the cooling fan.

A PWM duty may be in units of a percentage from 0 to 100 percent. The first and second PWM test signals are sufficiently distinct such that the cooling fan may be expected to operate at different fan speeds when receiving the first PWM test signal versus when receiving the second PWM test signal. For example, the first PWM test signal may be at 50% duty, and the second PWM test signal may be at 25% duty.

The storage medium 100 further includes fan speed signal receipt instructions 104 to cause the processor to receive a first fan speed signal in response to the first PWM test signal and a second fan speed signal in response to the second PWM test signal.

A fan speed signal may include an indication of the rotations per minute (RPM) of the cooling fan or similar. The first and second fan speed signals may be stored in a memory of the processor or the computing device for further calculation. For example, the first fan speed signal may be stored as “A” RPM, and the second fan speed signal may be stored as “B” RPM.

The storage medium 100 further includes PWM control determination instructions 106 to cause the processor to determine, when the first fan speed signal is not equal to the second fan speed signal, that the cooling fan is a PWM-controlled fan. For example, if “A” RPM is not equal to “B” RPM, then it is determined that the cooling fan is a PWM-controlled fan. Conversely, it may also be determined that, when the first fan speed signal is equal to the second fan speed signal, the cooling fan is not a PWM-controlled fan and is therefore a voltage-controlled fan. The determination may be a tentative determination to be verified by a further voltage control test.

The storage medium 100 further includes voltage test signal transmission instructions 108 to cause the processor to transmit first and second voltage test signals at different voltages to the fan connector.

The voltage test signals may be in direct current (DC) and in units of volts (V) appropriate to operate the cooling fan. For example, if the cooling fan operates between 0-12 V, and the processor transmits the voltage test signals directly to the fan connector, the voltage test signals may be between 0-12 V. In another example, if the cooling fan operates between 0-12 V, and the processor is connected to a voltage control (VC) fan controller which amplifies voltage control signals for transmission to the fan connector, the processor may submit voltage control signals to the VC fan controller between 0-3 V, resulting in voltage test signals at the fan connector between 0-12 V.

The first and second voltage test signals are sufficiently distinct such that the cooling fan may be expected to operate at different fan speeds when receiving the first voltage test signal versus when receiving the second voltage test signal. For example, if the processor is connected to a VC fan controller to transmit voltage test signals, the processor may transmit to the VC fan controller a voltage control signal at a voltage of 1.5 V, corresponding to a first voltage test signal of 6 V at the fan connector, and the processor may transmit to the VC fan controller a voltage control signal at 3 V, corresponding to a second voltage test signal of 12 V at the fan connector.

The storage medium 100 further includes fan speed signal receipt instructions 110 to cause the processor to receive a third fan speed signal in response to the first voltage test signal and a fourth fan speed signal in response to the second voltage test signal. The third and fourth fan speed signals may be stored in a memory of the processor or the computing device for further calculation. For example, the third fan speed signal may be stored as “C” RPM, and the fourth fan speed signal may be stored as “D” RPM.

The storage medium 100 further includes voltage control determination instructions 112 to cause the processor to determine, when the third fan speed signal is not equal to the fourth fan speed signal, that the cooling fan is a voltage-controlled fan. For example, if “C” RPM is not equal to “D” RPM, then it is determined that the cooling fan is a voltage-controlled fan. Conversely, it may also be determined that, when the third fan speed signal is equal to the fourth fan speed signal, the cooling fan is not a voltage-controlled fan and is therefore a PWM-controlled fan.

As with the PWM control determination, the voltage control determination may be a tentative determination to be verified by a further PWM control test. It is to be emphasized that PWM control testing and voltage control testing may be tested in either order provided that both forms of control are tested for redundancy. With such redundancy, the processor is able to determine whether any of the tentative PWM control or voltage control determinations were caused by a fault in the cooling fan rather than by PWM or voltage control.

Thus, the storage medium 100 may further include fault determination instructions to cause the processor to determine, when the first and second fan speed signals are not equal, and the third and fourth fan speed signals are not equal, that the cooling fan is faulty. Further, the storage medium may further include fault determination instructions to cause the processor to determine, when the first and second fan speed signals are equal, and the third and fourth fan speed signals are equal, that the cooling fan is faulty.

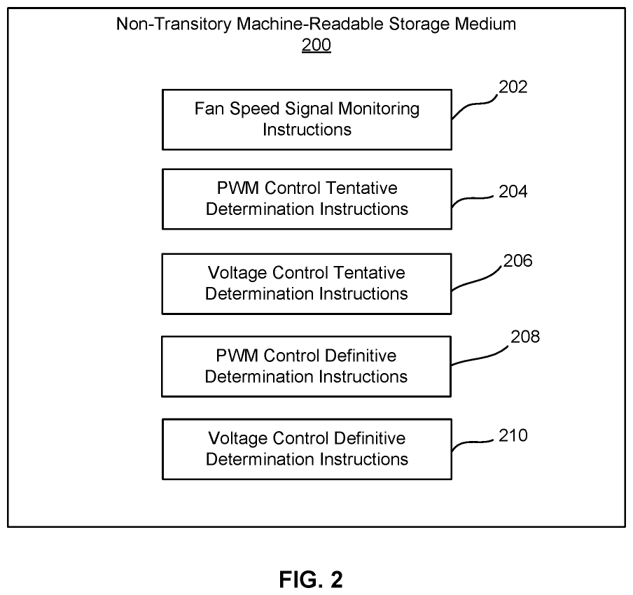

FIG. 2 is a schematic diagram of another example non-transitory machine-readable storage medium 200. The storage medium 200 stores instructions to cause a processor of a computing device to determine whether a cooling fan connected to a fan connector is a PWM-controlled fan or a voltage-controlled fan. The computing device may include a desktop computer, laptop computer, or any other computing device that is capable of operating with four-pin PWM-controlled fans and three-pin voltage-controlled fans through fan connectors that may connect to either type of cooling fan. The processor may include an embedded controlled connected to a motherboard of the computing device to which the fan connector is connected.

The storage medium 200 includes fan speed signal monitoring instructions 202 to cause the processor to monitor fan speed signals received from the fan connector connected to the cooling fan. The fan speed signals may include indications of the RPM of the cooling fan or similar.

The storage medium 200 further includes PWM control tentative determination instructions 204 to cause the processor to cause different PWM test signals at different PWM duties to be transmitted to the cooling fan through the fan connector, and tentatively determine that the cooling fan is a PWM-controlled fan if it is monitored that the fan speed signals change when PWM test signals at different PWM duties are transmitted to the cooling fan. Thus, the PWM control tentative determination instructions 204 may be similar to the instructions 102, 104, and 106 of the storage medium 100 of FIG. 1.

The storage medium 200 further includes voltage control tentative determination instructions 206 to cause the processor to cause different voltage test signals at different voltages to be transmitted to the cooling fan through the fan connector, and tentatively determine that the cooling fan is a voltage-controlled fan it is monitored that the fan speed signals change when voltage test signals at different voltages are transmitted to the cooling fan. Thus, the voltage control tentative determination instructions 206 may be similar to the instructions 108, 110, and 112 of the storage medium 100 of FIG. 1.

The storage medium 200 further includes PWM control definitive determination instructions 208 to cause the processor to definitively determine that the cooling fan is a PWM-controlled fan if it is tentatively determined that the cooling fan is a PWM-controlled fan and it is not tentatively determined that the cooling fan is a voltage-controlled fan. The storage medium 200 further includes voltage control definitive determination instructions 210 to cause the processor to definitively determine that the cooling fan is a voltage-controlled fan if it is tentatively determined that the cooling fan is a voltage-controlled fan and it is not tentatively determined that the cooling fan is a PWM-controlled fan.

Further, the storage medium 200 may further include instructions to cause the processor to determine, if it is tentatively determined that the cooling fan is a PWM-controlled fan and further tentatively determined that the cooling fan is a voltage-controlled fan, that the cooling fan is faulty. Further, the storage medium 200 may further include instructions to cause the processor to determine, if it is not tentatively determined that the cooling fan is a PWM-controlled fan and further not tentatively determined that the cooling fan is a voltage-controlled fan, that the cooling fan is faulty.

The instructions 204 and 208 may be executed in either order, and similar, once the instructions 204 and 208 have been executed, the instructions 206 and 210 may be executed in either order. In other words, tests may be conducted for PWM control and voltage control in any order. Thus, the storage medium 200 may further include instructions to cause the processor to cause the different PMW test signals to be transmitted to the cooling fan prior to causing the different voltage test signals to be transmitted to the cooling fan. Further, the storage medium 200 may further include instructions to cause the processor to cause the different voltage test signals to be transmitted to the cooling fan prior to causing the different PWM test signals to be transmitted to the cooling fan.

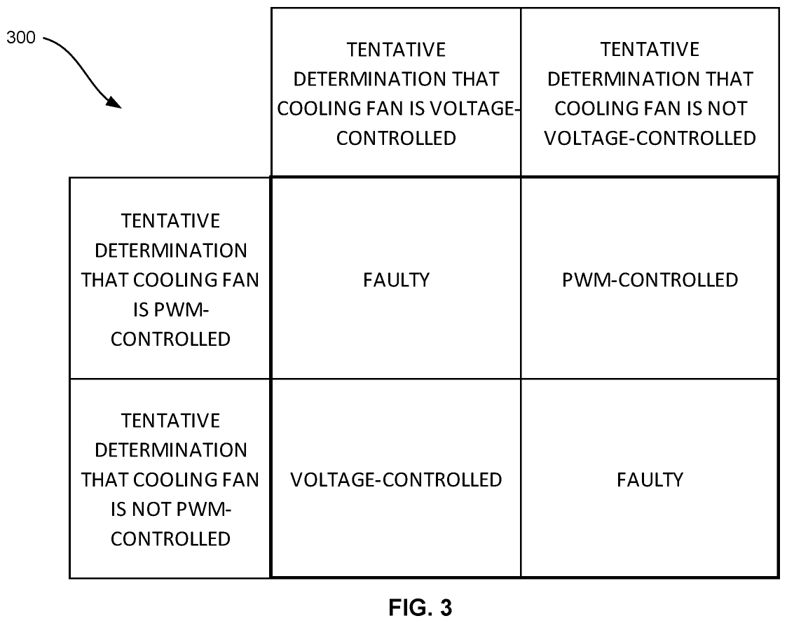

The above-described testing procedure provides redundancy for the processor to determine whether the PWM tests and voltage tests factually indicate whether the cooling fan is PWM-controlled, voltage-controlled, or whether the test results indicate that the cooling fan is faulty. This decision-making logic may be instantiated in a decision-making matrix stored in memory of the processor or computing device. FIG. 3 provides an example of such a decision-making matrix 300. The processor of the computing device may reference the decision-making matrix 300 after making tentative determinations as to whether the cooling fan is PWM-controlled or voltage-controlled to come to a definitive determination as to whether the cooling fan is PWM-controlled, voltage-controlled, or whether the cooling fan is faulty.

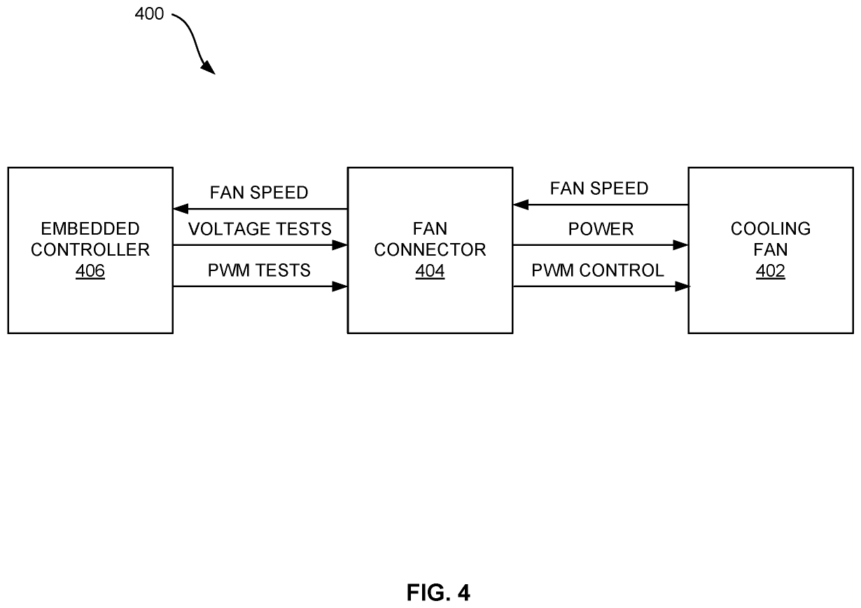

FIG. 4 is a schematic diagram of an example device 400. The device 400 includes a cooling fan 402, a fan connector 404 to connect to the cooling fan 402, and an embedded controller 406 to determine whether the cooling fan 402 is a PWM-controlled fan or a voltage-controlled fan. The device 400 may be part of a computing device such as a desktop computer, laptop computer, or any other computing device that is capable of operating with four-pin PWM-controlled fans and three-pin voltage-controlled fans through fan connectors that may connect to either type of cooling fan. The embedded controller 406 may be embedded in a motherboard of such a computing device.

The cooling fan 402 is to cool the device 400. For example, if the device 400 is part of a desktop computer, the cooling fan 402 may be a case fan to cool provide generalized cooling to the computer.

The fan connector 404 is to receive fan speed signals from the cooling fan 402, transmit power to the cooling fan 402, and transmit pulse-width-modulation (PWM) control signals to the cooling fan 402. Thus, the fan connector may be a four-pin connector including pins for ground, power, fan speed detection, and PWM control.

The embedded controller 406 is to monitor the fan speed signals, make tentative determinations as to whether the cooling fan 402 is PWM-controlled or voltage-controlled, and to make a definitive determination based on the tentative determinations.

The embedded controller 406 tests whether the fan speed signals change in response to the cooling fan 402 receiving different pulse width modulation test signals to make a tentative determination of whether the cooling fan 402 is a PWM-controlled fan. These tests for PWM control may be similar to instructions 102, 104, and 106 of FIG. 1, or instructions 204 of FIG. 2.

The embedded controller 406 further tests whether the fan speed signals change in response to the cooling fan 402 receiving different voltage test signals to make a tentative determination of whether the cooling fan 402 is a voltage-controlled fan. These tests for voltage control may be similar to instructions 108, 110, and 112 of FIG. 1, or instructions 206 of FIG. 2.

The embedded controller 406 further definitively determines whether the cooling fan 402 is a PWM-controlled fan or a voltage-controlled fan based on the tentative determinations. Making a definitive determination may be similar to instructions 208 or 210 of FIG. 2. Further, a definitive determination may be made, including a determination as to whether the cooling fan 402 is faulty, with reference to a decision-making matrix stored in memory of the device 400, such as the decision-making matrix 300 of FIG. 3. Thus, the embedded controller 406 may further be to definitively determine that the cooling fan is faulty when the tentative determinations contradict.

After testing, the embedded controller 406 may proceed to operate the cooling fan 402 according to PWM control when it is determined that the cooling fan 402 is PWM-controlled, or may proceed to operate the cooling fan 402 according to voltage control when it is determined that the cooling fan 402 is voltage-controlled.

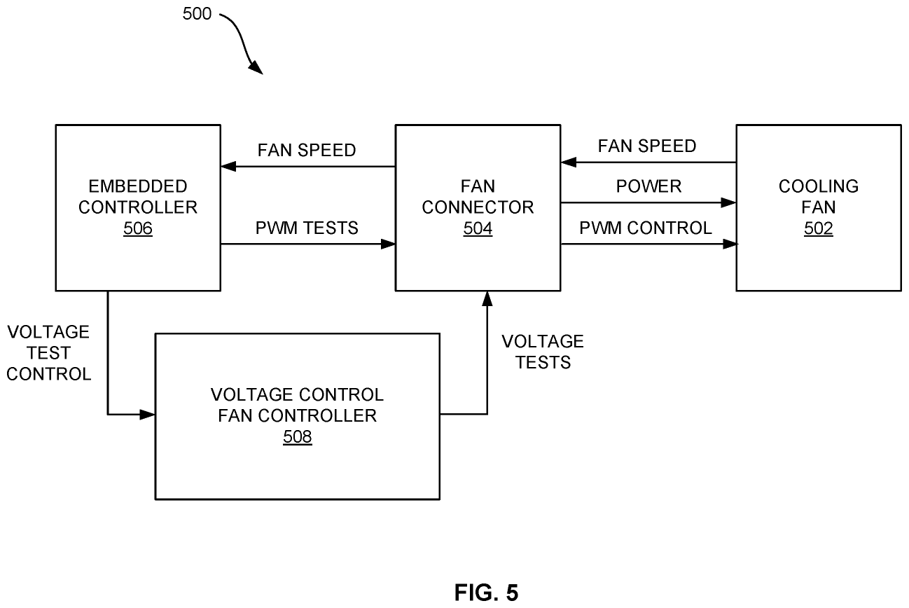

FIG. 5 is a schematic diagram of another example device 500 including a cooling fan 502, a fan connector 504 to connect to the cooling fan 502, and an embedded controller to determine whether the cooling fan 502 is a PWM-controlled fan or a voltage-controlled fan. The device 500 may be similar to the device 400 of FIG. 4, and thus for further description of the cooling fan 502, fan connector 504, and embedded controller 506, reference may be had to the cooling fan 402, fan connector 404, and embedded controller 406 of FIG. 4.

In contrast to the device 400 of FIG. 4, the device 500 further includes a voltage control (VC) fan controller to power the cooling fan 502 through the fan connector 504. Further, the embedded controller 506 causes the VC fan controller 508 to power the cooling fan 502 with the different voltage test signals to test whether the cooling fan 502 changes fan speed in response to the cooling fan 502 receiving different voltage test signals. Thus, while the embedded controller 506 transmits PWM test signals to the fan connector 504 directly, the embedded controller 506 transmits voltage test signals to the fan connector 504 through the VC fan controller 508.

Thus, it should be seen that a cooling fan may be tested to determine whether the cooling fan is PWM-controlled, voltage-controlled, or faulty, without expensive electronic components and circuitry, without computationally intensive testing procedures, and with inherent redundancy for reliable testing.

It should be recognized that features and aspects of the various examples provided above can be combined into further examples that also fall within the scope of the present disclosure. The scope of the claims should not be limited by the above examples but should be given the broadest interpretation consistent with the description as a whole.

1. A non-transitory machine-readable storage medium comprising instructions that when executed cause a processor of a computing device to:
transmit first and second pulse width modulation (PWM) test signals at different PWM duties to a fan connector connected to a cooling fan;
receive a first fan speed signal in response to the first PWM test signal and a second fan speed signal in response to the second PWM test signal;
determine, when the first fan speed signal is not equal to the second fan speed signal, that the cooling fan is a PWM-controlled fan;
transmit first and second voltage test signals at different voltages to the fan connector;
receive a third fan speed signal in response to the first voltage test signal and a fourth fan speed signal in response to the second voltage test signal; and
determine, when the third fan speed signal is not equal to the fourth fan speed signal, that the cooling fan is a voltage-controlled fan.

2. The non-transitory machine-readable storage medium of claim 1, wherein the instructions are further to cause the processor of the computing device to:
determine, when the first and second fan speed signals are not equal, and the third and fourth fan speed signals are not equal, that the cooling fan is faulty.

3. The non-transitory machine-readable storage medium of claim 1, wherein the instructions are further to cause the processor of the computing device to:
determine, when the first and second fan speed signals are equal, and the third and fourth fan speed signals are equal, that the cooling fan is faulty.

4. The non-transitory machine-readable storage medium of claim 1, wherein the instructions are further to cause the processor of the computing device to:
transmit the first and second voltage test signals through a voltage control (VC) fan controller connected to the fan connector.

5. A non-transitory machine-readable storage medium comprising instructions that when executed cause a processor of a computing device to:
monitor fan speed signals received from a fan connector connected to a cooling fan;
cause different pulse width modulation (PWM) test signals at different PWM duties to be transmitted to the cooling fan through the fan connector, and tentatively determine that the cooling fan is a PWM-controlled fan if it is monitored that the fan speed signals change when PWM test signals at different PWM duties are transmitted to the cooling fan;
cause different voltage test signals at different voltages to be transmitted to the cooling fan through the fan connector, and tentatively determine that the cooling fan is a voltage-controlled fan it is monitored that the fan speed signals change when voltage test signals at different voltages are transmitted to the cooling fan;
definitively determine that the cooling fan is a PWM-controlled fan if it is tentatively determined that the cooling fan is a PWM-controlled fan and it is further not tentatively determined that the cooling fan is a voltage-controlled fan; and
definitively determine that the cooling fan is a voltage-controlled fan if it is tentatively determined that the cooling fan is a voltage-controlled fan and it is further not tentatively determined that the cooling fan is a PWM-controlled fan.

6. The non-transitory machine-readable storage medium of claim 5, wherein the instructions are further to cause the processor of the computing device to:
determine, if it is tentatively determined that the cooling fan is a PWM-controlled fan and further tentatively determined that the cooling fan is a voltage-controlled fan, that the cooling fan is faulty.

7. The non-transitory machine-readable storage medium of claim 5, wherein the instructions are further to cause the processor of the computing device to:
determine, if it is not tentatively determined that the cooling fan is a PWM-controlled fan and further not tentatively determined that the cooling fan is a voltage-controlled fan, that the cooling fan is faulty.

8. The non-transitory machine-readable storage medium of claim 5, wherein the instructions are further to cause the processor of the computing device to:
cause the different PMW test signals to be transmitted to the cooling fan prior to causing the different voltage test signals to be transmitted to the cooling fan.

9. The non-transitory machine-readable storage medium of claim 5, wherein the instructions are further to cause the processor of the computing device to:
cause the different voltage test signals to be transmitted to the cooling fan prior to causing the different PWM test signals to be transmitted to the cooling fan.

10. A device comprising:
a fan connector to connect to a cooling fan, the fan connector to receive fan speed signals from the cooling fan, transmit power to the cooling fan, and transmit pulse-width-modulation (PWM) control signals to the cooling fan; and
an embedded controller to:
monitor the fan speed signals;
test whether the fan speed signals change in response to the cooling fan receiving different pulse width modulation test signals to make a tentative determination of whether the cooling fan is a PWM-controlled fan;
test whether the fan speed signals change in response to the cooling fan receiving different voltage test signals to make a tentative determination of whether the cooling fan is a voltage-controlled fan; and
definitively determine whether the cooling fan is a PWM-controlled fan or a voltage-controlled fan based on the tentative determinations.

11. The device of claim 10, wherein the embedded controller is further to definitively determine that the cooling fan is faulty when the tentative determinations contradict.

12. The device of claim 10, wherein the device further comprises a voltage control (VC) fan controller to power the cooling fan through the fan connector, and the embedded controller causes the VC fan controller to power the cooling fan with the different voltage test signals to test whether the cooling fan changes fan speed in response to the cooling fan receiving different voltage test signals.

13. The device of claim 10, wherein the embedded controller is to make the tentative determination of whether the cooling fan is a PWM-controlled fan prior to making the tentative determination of whether the cooling fan is a voltage-controlled fan.

14. The device of claim 10, wherein the embedded controller is to make the tentative determination of whether the cooling fan is a voltage-controlled fan prior to making the tentative determination of whether the cooling fan is a PWM-controlled fan.

15. The device of claim 10, wherein the embedded controller is further to operate the cooling fan according to PWM control when it is determined that the cooling fan is PWM-controlled and to operate the cooling fan according to voltage control when it is determined that the cooling fan is voltage-controlled.
